(19) United States
(12) Patent Application Publication
(10) Pub. No.: US 2010/0238725 A1
(43) Pub. Date: Sep. 23, 2010

(54) NONVOLATILE SEMICONDUCTOR STORAGE DEVICE AND METHOD OF PROGRAMMING DATA THEREIN

(75) Inventor: Kiyomi NARUKE, Sagamihara-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/727,888

(22) Filed: Mar. 19, 2010

(30) Foreign Application Priority Data
Mar. 23, 2009 (JP) 2009-070288

(51) Int. Cl. G11C 16/02; G11C 16/06

(52) U.S. Cl. 365/185.03; 365/185.22; 365/185.24

(57) ABSTRACT

Each of the memory cells stores multiple bits of data by way of a threshold voltage distribution having a negative value and representing an erase state, and a plurality of threshold voltage distributions each having a value higher than the threshold voltage distribution representing the erase state and representing a programming state. In a data programming operation, a control circuit applies a certain verify voltage to a control gate of one of the memory cells to be written to obtain a threshold voltage distribution higher than the threshold voltage distribution representing the erase state, thereby confirming the programming state of the memory cells. The control circuit also applies, in a data programming operation, a certain verify voltage to a control gate of one of the memory cells maintained in the erase state, thereby adjusting a lower limit value of the threshold voltage distribution representing the erase state.

### CROSS REFERENCE TO RELATED APPLICATIONS

This application is based on and claims the benefit of priority from prior Japanese Patent Application No. 2009-70288, filed on Mar. 23, 2009, the entire contents of which are incorporated herein by reference.

### BACKGROUND OF THE INVENTION

1. Field of the Invention

The present invention relates to a nonvolatile semiconductor memory device, in particular, to a nonvolatile semiconductor memory device configured using electrically rewritable nonvolatile memory cells, and a method of programming data therein.

2. Description of the Related Art

Demand for NAND flash memory is increasing rapidly, along with the increase in its applications handling large capacity data, such as photographic images and moving images in mobile devices and the like. In particular, the adoption of multi-value storage technology which allows two or more bits of information to be stored in one memory cell has made it possible to store a greater amount of information in a small chip area.

In highly integrated flash memory having advanced shrinking of a cell size, threshold distribution of memory cells is affected by interference between adjacent memory cells. In particular, in the case that a multi-value storage system is adopted, width and spacing of threshold distributions need to be set narrower than in a binary storage system, whereby interference between adjacent cells seriously affects reliability of data.

In consideration of this problem, a flash memory programming technology configured to prevent threshold distribution variations caused by capacitance coupling between floating gates of adjacent cells is disclosed in, for example, JP 2004-192789 A.

Now, in NAND cell flash memory, the threshold voltage of memory cells in the erase state is set to a negative value. As shrinking of a memory cell size advances and the effects of interference of adjacent memory cells increase, it is required to set this threshold voltage of memory cells in the erase state to an ever greater negative value. This is because the threshold voltage distribution of memory cells in the erase state may be affected by programming operations and so on to adjacent memory cells and thereby caused to shift gradually in the positive direction, leading eventually to the upper limit of the threshold distribution becoming a positive value. As a result, there is no choice but to set the threshold voltage distribution of memory cells in the erase state to an increasingly large negative value in accordance with developments in shrinking (it is required to set the erase verify voltage to a negative value of large absolute value).

However, memory cells in the erase state having this kind of threshold voltage distribution with a negative value of large absolute value are a cause of variation in the threshold voltage of adjacent memory cells.

### SUMMARY OF THE INVENTION

In accordance with a first aspect of the present invention, a nonvolatile semiconductor memory device comprises: a memory cell array having a plurality of memory cells arranged therein, each of the memory cells configured to store multiple bits of data by way of a threshold voltage distribution having a negative value and representing an erase state, and a plurality of threshold voltage distributions each having a value higher than the threshold voltage distribution representing the erase state and representing a programming state; and a control circuit configured to control a programming operation for storing data to the memory cells, a programming verify operation for confirming the data to the memory cells, and a read operation for reading the data from the memory cells, the control circuit being operative to apply, in the programming verify operation, a certain verify voltage to a control gate of one of the memory cells which is to be programmed to obtain a threshold voltage distribution higher than the threshold voltage distribution representing the erase state, thereby confirming the programming state of the memory cell, and apply, in the programming verify operation, a certain verify voltage to a control gate of one of the memory cells maintained in the erase state, thereby adjusting a lower limit value of the threshold voltage distribution representing the erase state.

In accordance with a second aspect of the present invention, a method of programming data in a nonvolatile semiconductor memory device, the nonvolatile semiconductor memory device including a memory cell array including a plurality of memory cells arranged therein, each of the memory cells configured to store multiple bits of data by way of a threshold voltage distribution having a negative value and representing an erase state, and a plurality of threshold voltage distributions each having a value higher than the threshold voltage distribution representing the erase state and representing a programming state, the method comprising: applying a certain verify voltage to a control gate of one of the memory cells which is to be programmed to obtain a threshold voltage distribution higher than the threshold voltage distribution representing the erase state, thereby confirming the programming state of the memory cell; and applying a certain verify voltage to a control gate of one of the memory cells that is to be maintained in the erase state, thereby adjusting a lower limit value of the threshold voltage distribution representing the erase state.

### BRIEF DESCRIPTION OF THE DRAWINGS

FIG. 1 shows an example of programming data in a four-value storage flash memory.

FIG. 2 is a conceptual diagram showing a data programming procedure in the four-value storage flash memory.

FIG. 3 is a conceptual diagram showing a data programming procedure in the four-value storage flash memory.

FIG. 4 is an explanatory view describing a problem focused on by the present invention.

FIG. 5 is an explanatory view describing a problem focused on by the present invention.

FIG. 6 is an explanatory view describing a problem focused on by the present invention.

FIG. 7 shows a data programming method in a nonvolatile semiconductor memory device in accordance with a first embodiment of the present invention.

FIG. 8 shows the data programming method in the nonvolatile semiconductor memory device in accordance with the first embodiment of the present invention.

FIG. 9 is a block diagram showing a schematic configuration of a NAND cell flash memory according to the first embodiment of the present invention.

FIG. 10 is a circuit diagram showing a configuration of a memory cell array 1 and a bit line control circuit 2 shown in FIG. 9.

FIG. 11 is a cross-sectional view of a memory cell MC in FIG. 10.

FIG. 12 is a cross-sectional view of select gates S1 and S2 in FIG. 10.

FIG. 13 is a cross-sectional view showing one NAND cell in the memory cell array.

FIG. 14 is a circuit diagram showing an exemplary configuration of a data storage circuit 10.

FIG. 15A is a flowchart describing a multi-value programming operation and a programming verify operation in the NAND cell flash memory of the first embodiment.

FIG. 15B is another flowchart describing a multi-value programming operation and a programming verify operation in the NAND cell flash memory of the first embodiment.

FIG. 16 is a flowchart describing the multi-value programming operation and the programming verify operation in the NAND cell flash memory of the first embodiment.

FIG. 17A is a conceptual diagram showing a data programming method in a nonvolatile semiconductor memory device in accordance with a second embodiment of the present invention.

FIG. 17B is a flowchart showing a data programming operation of a nonvolatile semiconductor memory device in accordance with a second embodiment of the present invention.

FIG. 17C is a flowchart showing a data programming operation of a nonvolatile semiconductor memory device in accordance with a second embodiment of the present invention.

FIG. 18 is a conceptual diagram showing a procedure in a method of data programming in the second embodiment of the present invention.

### DETAILED DESCRIPTION OF THE EMBODIMENTS

Next, embodiments of the present invention are described in detail with reference to the drawings, taking a four-value storage system NAND cell flash memory as an example.

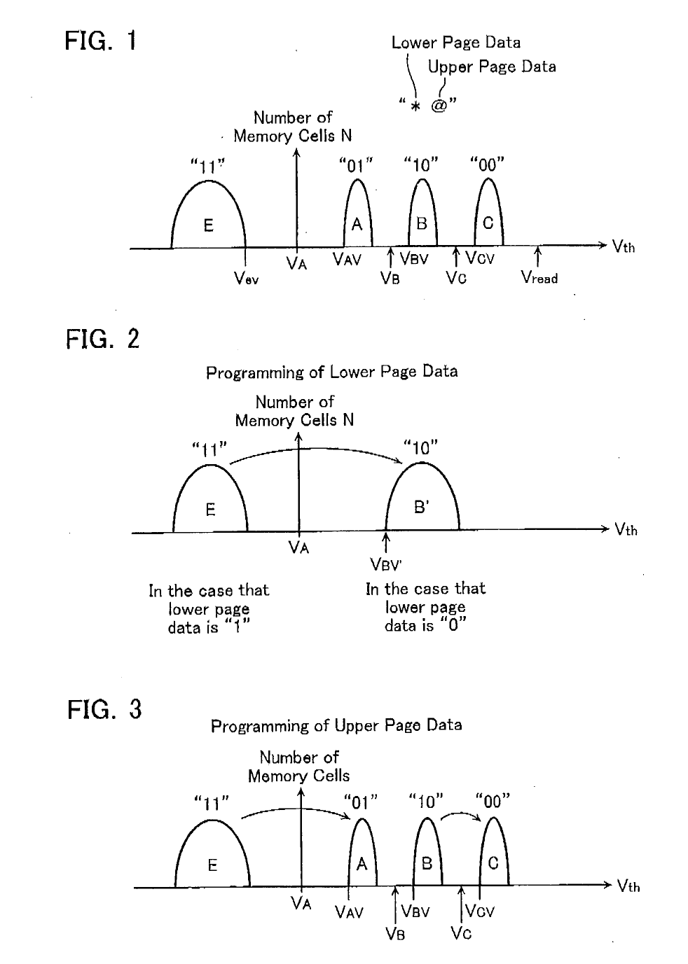

First, an overview of a programming system in a general four-value storage system NAND cell flash memory is described. A four-value NAND cell flash memory is configured such that threshold voltage of one memory cell has four distributions. FIG. 1 shows the relationship between two-bit four-value data (data “11”, “10”, “01”, and “00”) stored in a memory cell and threshold voltage distributions of the memory cell in the four-value NAND cell flash memory. Note that, in FIG. 1, VA, VB, and VC are voltages applied to a selected word line in case of reading the four-value data (voltage VA is 0 V). VAV, VBV, and VCV represent verify voltages applied to confirm whether or not a programming operation to obtain any one of the threshold voltage distributions is completed when programming is finished. In addition, Vread represents a read voltage that is applied to unselected memory cells among the NAND cells when reading data of the memory cells and renders the unselected memory cells conductive irrespective of data stored therein. Furthermore, Vev is an erase verify voltage applied to a memory cell to confirm whether or not erase is completed when erasing data of the memory cells, and has a negative value. The value of Vev is determined of interference caused by adjacent memory cells. The relation of each of the above-mentioned voltages is Vev<VA<VAV<VB<VBV<VC<VCV<Vread.

Note that, although, as previously mentioned, the erase verify voltage Vev has a negative value, a voltage actually applied to a control gate of a memory cell MC in an erase verify operation is zero or a positive value, not a negative value. That is, in the actual erase verify operation, a back gate of the memory cell MC is provided with a positive voltage, and the control gate of the memory cell MC is applied with zero or a voltage of a positive value less than that of the back gate voltage. In other words, the erase verify voltage Vev is a voltage having a negative value in an equivalent sense.

A threshold voltage distribution E of memory cells subsequent to block erase has an upper limit value that is also a negative value, and is assigned with data “11”, In addition, memory cells of data “01”, “10”, and “00” in a programming state have positive threshold voltage distributions A, B, and C, respectively (lower limit values of A, B, and C are also positive values). The threshold voltage distribution A of data “01” has a lowest voltage value, the threshold voltage distribution C of data “00” has a highest voltage value, and the threshold voltage distribution of data “10” has a voltage value intermediate between those of data “01” and data “00”. Note that the threshold voltage distributions shown in FIG. 1 are no more than an example, and the present invention is not limited to these. For example, a description is provided assuming that the threshold voltage distributions in FIG. 1 are all positive threshold voltage distributions. However, cases such as where the threshold voltage distribution A is a negative voltage distribution and the threshold voltage distributions B and C are positive voltage distributions are also included in the range of the present invention. The threshold voltage distribution E should be a negative voltage distribution.

Two-bit data of one memory cell is comprised of lower page data and upper page data, and the lower page data and upper page data are stored to the memory cell by separate programming operations, in other words, in two programming operations. When data “*@” is stored, the * represents upper page data, and the @ represents lower page data.

First, programming of lower page data is described with reference to FIG. 2. It is assumed that the threshold voltage of all memory cells is included the threshold voltage distribution E of the erase state and are storing data “11”. As shown in FIG. 2, when programming of lower page data, the threshold voltage distribution E divides into two threshold voltage distributions (E, B′), according to a value of the lower page data (“1” or “0”). That is, in the case that the value of the lower page data is “1”, the threshold voltage distribution E of the erase state is maintained.

In contrast, when the value of the lower page data is “0”, the tunnel oxide film of the memory cell is applied with an intense electric field, whereby electrons are injected into the floating gate electrode, thus raising a threshold voltage Vth of the memory cell by a certain amount. Specifically, a verify voltage VBV′ is set, and the programming operation is repeated until a threshold voltage greater than or equal to this verify voltage VBV′ is attained. As a result, the memory cell changes to the programming state (data “10”). Note that the threshold voltage distribution B′ of data “10” has a broader distribution than that of data “11” due to effects of the programming operation on adjacent cells.

Next, programming of upper page data is described with reference to FIG. 3. Programming of upper page data is performed based on data inputted from outside of the chip (upper page data) and on the lower page data already stored to the memory cell. That is, as shown in FIG. 3, when a value of the upper page data is “1”, the tunnel oxide film of the memory cell is prevented from being applied with an intense electric field; thereby preventing a rise in the threshold voltage Vth of the memory cell. As a result, the memory cell of data “11” (threshold voltage distribution E of the erase state) maintains data “11” as is, and the memory cell of data “10” (threshold voltage distribution B′) maintains data “10” as is. However, a regular verify voltage VBV greater than the above-mentioned verify voltage VBV′ is used to adjust a lower limit value of the threshold voltage distribution, thereby forming a threshold voltage distribution B of narrowed width.

In contrast, in the case that the value of the upper page data is “0”, the tunnel oxide film of the memory cell is applied with an intense electric field, whereby electrons are injected into the floating gate electrode, thus raising a threshold voltage Vth of the memory cell by a certain amount. As a result, the memory cell of data “11” (threshold voltage distribution E of the erase state) changes to data “01” of the threshold voltage distribution A, and the memory cell of data “10” changes to data “00” of the threshold voltage distribution C. At this time, verify voltages VAV and VCV are used to adjust lower limit values of the threshold voltage distributions A and C.

The above is one example of the programming data method in a general four-value storage system. A multi-bit storage system of three or more bits merely adds to the above-described operation an operation of dividing the threshold voltage distributions into eight threshold voltage distributions corresponding to an additional upper page of page data, and basic operation is thus similar.

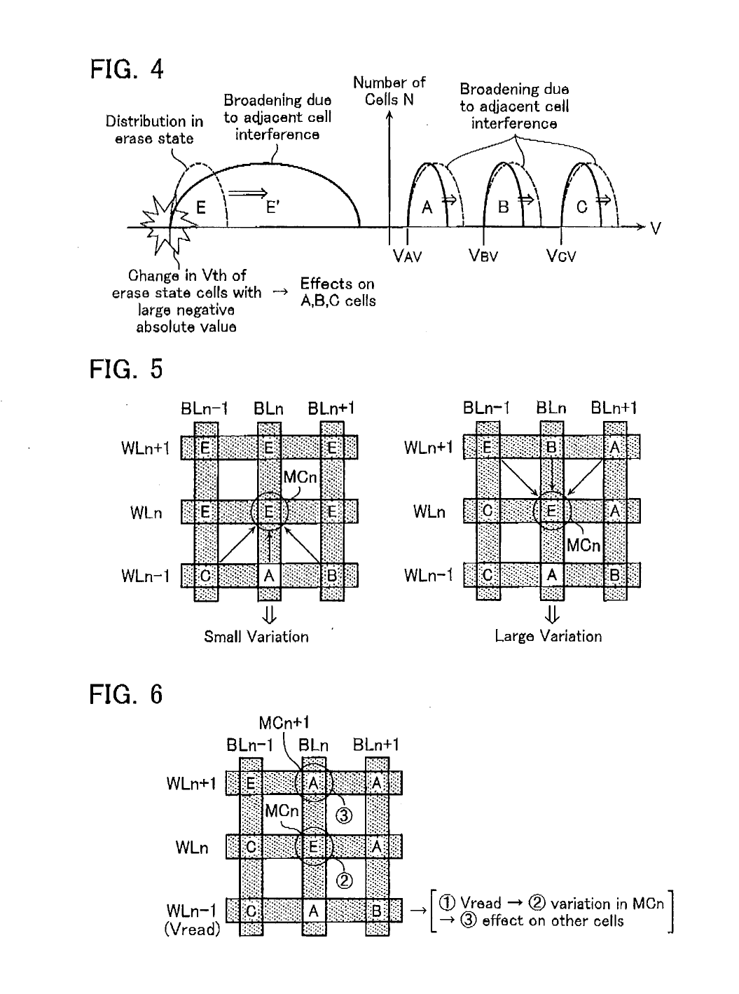

As shown in FIG. 4, an operation in an adjacent memory cell sometimes causes such multiple threshold voltage distributions to vary, even after completion of the programming data operation therefor. Various technologies are proposed to suppress an amount of variation in the threshold voltage distributions A, B, and C even after completion of the programming data operation. The various technologies include, for example, innovations in programming sequence to adjacent memory cells and so on. Moreover, in programming of the threshold voltage distributions A, B, and C, operations are performed in which verify voltages VAV, VBV, and VCV are respectively set for each of the distributions A, B, and C, thereby narrowing distribution widths.

At the same time, the threshold voltage distribution E of the erase state also sometimes varies due to adjacent memory cells, similarly to the threshold voltage distributions A, B, and C. For example, as shown in FIG. 4, a distribution E that has a narrow width immediately after an erase operation may become a distribution E′ that has a broader width. Such a broadening of the distribution is due to the following reasons. That is, as shown on the left-hand side of FIG. 5, a memory cell MCn is in the erase state, and there exist memory cells in the periphery of the memory cell MCn. If most of the memory cells in the periphery of the memory cell MCn are kept to threshold voltage distributions of the erase state (E), the threshold voltage of the memory cell MCn does not change a lot.

In contrast, if the memory cells in the periphery of the memory cell MCn are programmed to the threshold voltage distributions of A, B, and C (data “01”, “00”, and “10”), as shown on the right-hand side of FIG. 5, the amount of variation in the threshold voltage of the memory cell MCn increases. In particular, in the case that many of the adjacent memory cells are of threshold voltage distribution C, the amount of variation in the threshold voltage of the memory cell MCn also increases. Accordingly, the memory cells in the erase state may be influenced differently, depending on the programming state of adjacent memory cells. This causes the threshold voltage distribution E′ to be broadened in width, as described above.

Even if the width of the threshold voltage distribution of the memory cell in the erase state is broadened in this way, there will be no problem in read of the memory cell in the erase state itself, unless the upper limit value of the distribution exceeds the voltage VA (the memory cell in the erase state, that is, data “11”, will not be misread as other data). However, the inventor in the present application found that, if the lower limit value of such a broadened threshold voltage distribution E′ is left low, this lower limit value may conversely cause variation in the threshold voltage of the adjacent memory cells surrounding this memory cell MCn.

For example, as shown in FIG. 6, if a read voltage Vread is applied to a word line WLn−1 adjacent to a memory cell MCn in the erase state having such a low threshold voltage ((1)), this read voltage Vread affects the threshold voltage Vth of the memory cell MCn. That is, this causes the threshold voltage Vth of the memory cell MCn to change ((2)). This may result in a variation in the threshold voltage of an adjacent memory cell, for example MCn+1 ((3)). The greater the absolute value of the negative threshold voltage of the memory cell MCn in the erase state, the greater the amount of variation in threshold voltage Vth of the memory cell MCn in the erase state when a certain voltage (for example, a voltage Vread (about 4.5 V) applied to an unselected memory cell in a NAND string during a read operation) is applied to an adjacent memory cell. If the threshold voltage Vth of the memory cell MCn in the erase state undergoes a large variation, that in turn causes the threshold voltage of another adjacent memory cell to change. In this way, a large absolute value of the negative threshold voltage Vth of the memory cell MCn in the erase state causes the threshold voltage Vth in adjacent memory cells to vary.

The explanatory view of FIG. 6 is merely a single example, and a similar phenomenon may also occur in other adjacent memory cells. As previously mentioned, as the memory cell size is more shrunken, an erase verify voltage Vev tends to be set lower. However, the lower the erase verify voltage Vev is set, the greater becomes the difference between the read voltage Vread and the threshold voltage of the memory cell MCn in the erase state, whereby a problem such as that of FIG. 6 may no longer be ignored.

### FIRST EMBODIMENT

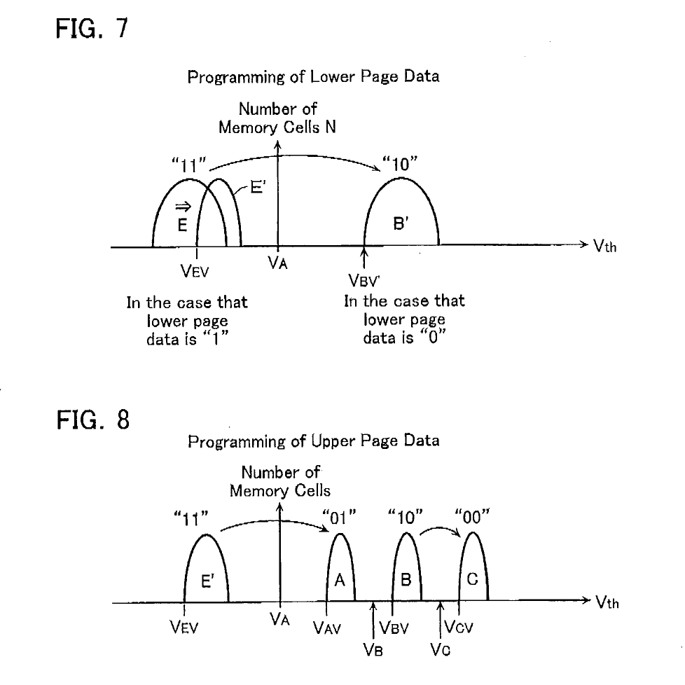

In view of this problem, the inventor of the present invention proposes a programming method as shown in FIGS. 7 and 8. FIGS. 7 and 8 show a programming data method in a nonvolatile semiconductor memory device in accordance with a first embodiment of the present invention (FIG. 7 shows programming of lower page data, and FIG. 8 shows programming of upper page data). The difference from a known procedure for programming is that, even in a memory cell MC that is to be left at threshold voltage distribution E, a verify voltage VEV is used to adjust the lower limit value of the threshold voltage distribution E. This verify voltage VEV is a voltage having a negative value in an equivalent sense, similarly to the erase verify voltage Vev.

This verify voltage VEV is set with consideration for the value of the above-mentioned read voltage Vread. That is, the value of the verify voltage VEV is set such that variation in the threshold voltage distribution due to the read voltage Vread is negligible, and such that, if such variation occur, the upper limit of the threshold voltage distribution E does not come close to (or does not exceed) the voltage VA.

Adjusting the lower limit value of the threshold voltage distribution E in this way causes the threshold voltage distribution E to be shifted in the positive direction and set to threshold voltage distribution E′. As a result, in a situation such as FIG. 6, the difference between the read voltage Vread and the threshold voltage Vth of the memory cell in the erase state is reduced, whereby it is possible to suppress the above-mentioned problem. Note that, in the example shown in FIGS. 7 and 8, the lower limit value of the threshold voltage distribution E is adjusted by applying the verify voltage only at the programming lower-page data. However, the present invention is not limited to this example, and a separate adjustment operation of the lower limit value of the threshold voltage distribution E may be included also in the stage of FIG. 8.

In this case, it is also possible that no data is assigned to the threshold voltage distribution E representing the erase state, but an additional or separate programming operation is performed to allocate data only to the newly-formed threshold voltage distribution. However, in the present embodiment, data is allocated also to the threshold voltage distribution E′ obtained by using the verify voltage VEV to adjust the lower limit value of the threshold voltage distribution E representing the erase state, and a additional programming is therefore not required. As a result, a speed of the programming operation can be improved.

[Memory Configuration]

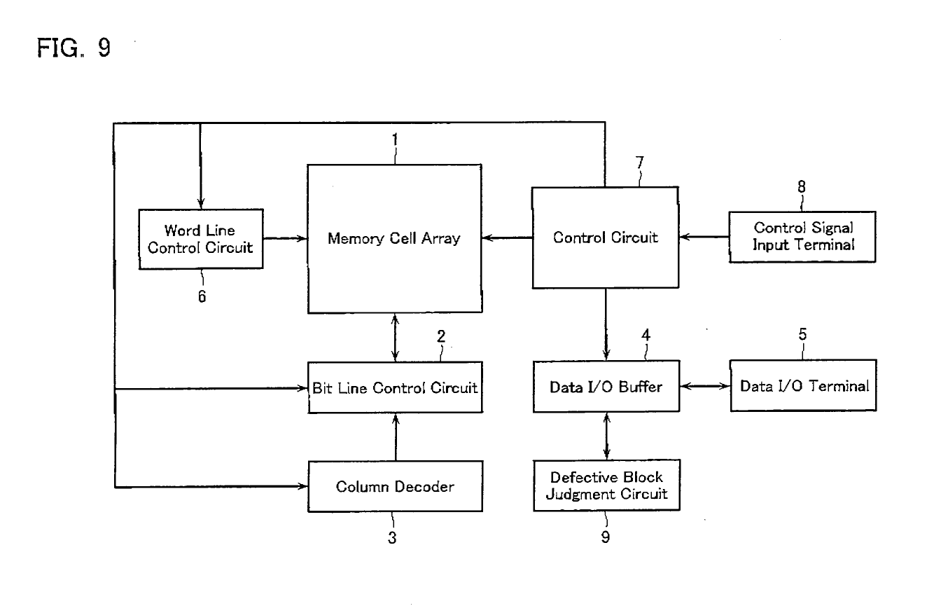

FIG. 9 shows a configuration of a NAND cell flash memory adopting a four-value storage system according to the first embodiment of the present invention. This flash memory comprises a memory cell array 1 having memory cells arranged in a matrix therein, the memory cells being configured to store data. The memory cell array 1 includes a plurality of bit lines, a plurality of word lines, and a common source line, and has the memory cells which are electrically data-rewritable disposed in a matrix at crossing-points of the bit lines and word lines.

Connected to this memory cell array 1 are a bit line control circuit 2 for controlling the bit lines, and a word line control circuit 6 for controlling a word line voltage. That is, the bit line control circuit 2 reads data of the memory cells in the memory cell array via the bit lines, and, in addition, applies a programming control voltage to the memory cells in the memory cell array 1 via the bit lines to perform programming to the memory cells.

Connected to the bit line control circuit 2 are a column decoder 3, a data I/O (input/output) buffer 4, and a data I/O terminal 5. Data of the memory cells read from the memory cell array 1 is outputted to outside from the data I/O terminal via the bit line control circuit 2 and the data I/O buffer 4. Moreover, programming data inputted to the data I/O terminal 5 from outside is inputted to the bit line control circuit 2 by means of the column decoder 3 via the data I/O buffer 4, whereby programming to specified memory cells is performed.

In addition, the memory cell array 1, the bit line control circuit 2, the column decoder 3, the data I/O buffer 4, and the word line control circuit 6 are connected to a control circuit 7. The control circuit 7 generates control signals and control voltages for controlling the memory cell array 1, the bit line control circuit 2, the column decoder 3, the data I/O buffer 4, and the word line control circuit 6 in accordance with control signals inputted to a control signal input terminal 8.

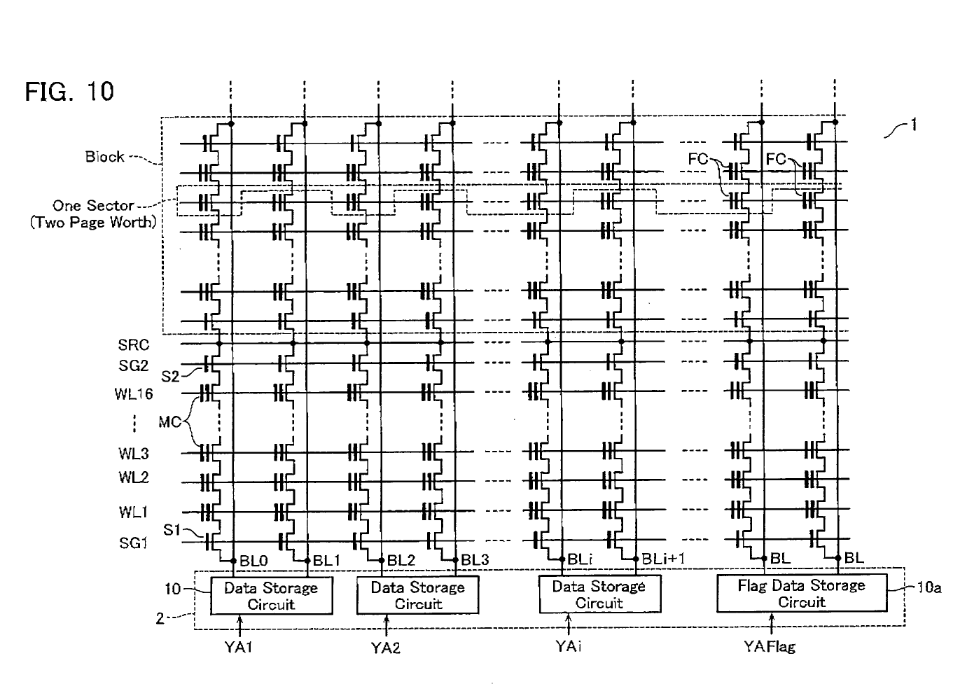

FIG. 10 shows a configuration of the memory cell array 1 and the bit line control circuit 2 shown in FIG. 9. The memory cell array 1 is a NAND cell memory cell array and is configured to include a plurality of NAND cells. One NAND cell is constituted by, for example, 16 memory cells MC of EEPROM configuration connected in series, and select gates S1 and S2 connected one to each end of the NAND cell. The select gate S1 is connected to a bit line BL0, and the select gate S2 is connected to a source line SRC. Control gates of memory cells MC disposed in an identical row are commonly connected to word lines WL1-WL16. In addition, first select gates S1 are commonly connected to a select line S1, and second select gates S2 are commonly connected to a select line S2.

The memory cell array 1 includes a plurality of blocks, as shown by the broken lines. Each of the blocks is configured by a plurality of the NAND cells, and data is erased in units of these blocks. Moreover, an erase operation is performed simultaneously for the two bit lines connected to data storage circuits 10 and a flag data storage circuit 10a.

The bit line control circuit 2 includes a plurality of the data storage circuits 10 and the flag data storage circuit 10a. Connected to each of the data storage circuits 10 and the flag data storage circuit 10a are pairs of bit lines (DL0, BL1), (BL2, BL3) (BLi, BLi+1), and (BL, BL). Each of the data storage circuits 10 functions to retain data read from the memory cells, and also functions to retain data to be written to the memory cells. In addition, each of the data storage circuits 10 has the role of manipulating internal data when multi-value storage is performed, as mentioned hereafter.

Furthermore, the plurality of memory cells disposed on every other bit line and connected to one of the word lines (the memory cells surrounded by the broken lines) configure one sector. Data is written and read in units of this sector, that is, on a sector-by-sector basis. One sector stores, for example, two pages worth of data. In addition, there are flag cells FC for storing flag data FLAG connected to each of the word lines. As previously mentioned, the flag data FLAG stored in these flag cells FC is set to “1” at the stage when the programming operation of lower page data to the memory cells MC is completed, and is set to “0” at the stage when programming of upper page data is completed.

During the read operation, the program verify operation, and the program operation, one bit line of the two bit lines (BLi, BLi+1) connected to the data storage circuit 10 is selected in response to externally-designated address signals (YA1, YA2 . . . YAi, YAflag). Further, one word line is selected in response to an external address, whereby one sector (two pages worth) is selected. Switching of these two pages is performed by address.

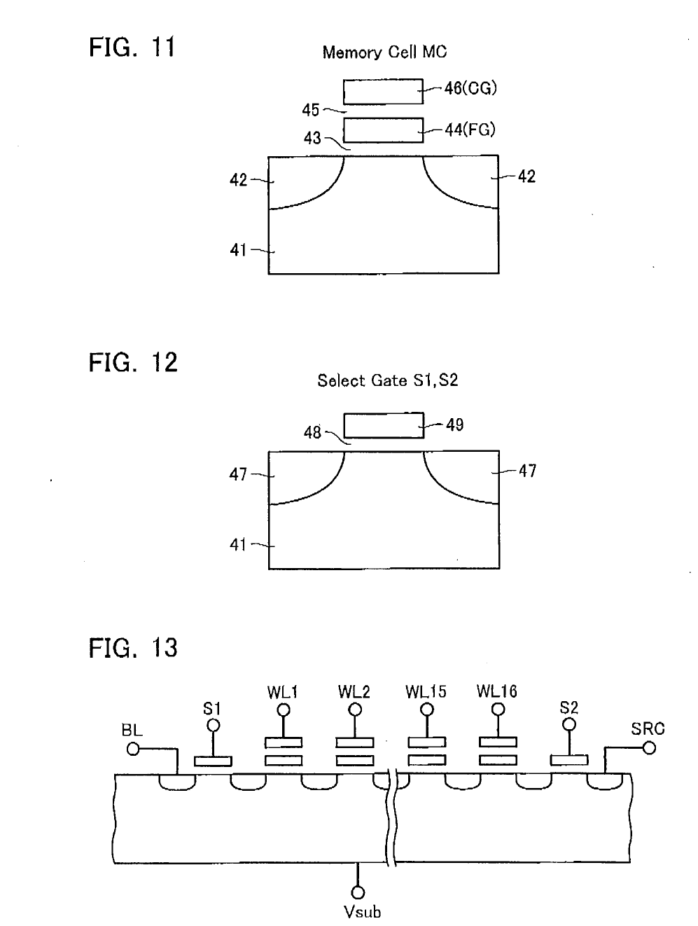

FIGS. 11 and 12 show cross-sectional structures of the memory cell MC, and of the select gates S1 and S2, respectively. FIG. 11 shows the cross-sectional structure of the memory cell MC. N-type diffusion layers 42 are formed on a substrate 41 that function as the source and drain of a MOSFET configuring the memory cell MC. In addition, a floating gate (FG) 44 is formed on the substrate 41 via agate insulating film 43, and a control gate (CG) 46 is formed on this floating gate 44 via an insulating film 45.

Each of the select gates S1 and S2 comprises the substrate 41 and n-type diffusion layers 47 formed on the substrate 41 as its source and drain. A control gate 49 is formed on the substrate 41 via a gate insulating film 48.

FIG. 13 shows a cross section of one NAND cell of the memory cell array. In this example, one NAND cell includes 16 memory cells MC configured as shown in FIG. 11, which memory cells are connected in series. Provided at the drain and source sides of the NAND cell are first select gates S1 and S2 configured as shown in FIG. 12.

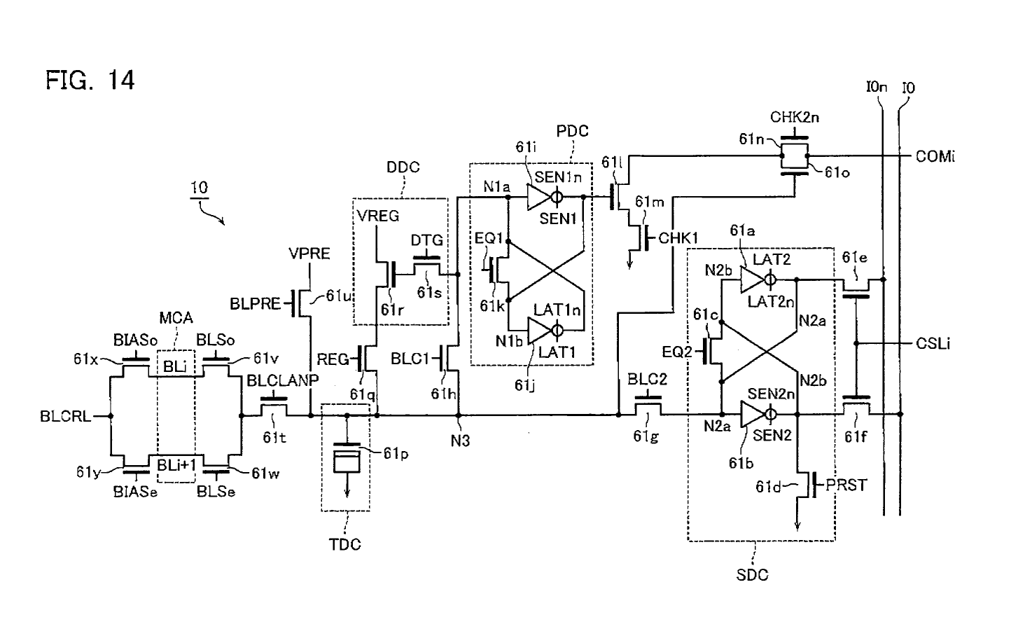

An exemplary configuration of the data storage circuit 10 is described with reference to FIG. 14. Note that a configuration of the flag data storage circuit 10a is substantially similar, and description thereof is thus omitted. The data storage circuit 10 includes a primary data cache (PDC), a secondary data cache (SDC), a dynamic data cache (DDC), and a temporary data cache (TDC).

The SDC, PDC, and DDC retain input data during programming, retain read data during read, retain data temporarily during verify, and control data storage for manipulation of internal data when storing multi-value data. The TDC amplifies data in the bit line and temporarily retains the data during read of data, and is also used in the manipulation of internal data when storing multi-value data.

The SDC comprises clocked inverter circuits 61a and 61b, and transistors 61c and 61d which configure a latch circuit. The transistor 61c is connected between an input terminal of the clocked inverter circuit 61a and an input terminal of the clocked inverter circuit 61b, and has its gate supplied with a signal EQ2.

The transistor 61d is connected between an output terminal of the clocked inverter circuit 61b and ground, and has its gate supplied with a signal PRST.

In addition, anode N2a (an output terminal of the clocked inverter circuit 61a) of the SDC is connected to an I/O data line IOn via a column select transistor 61e. Moreover, a node N2b (the output terminal of the clocked inverter circuit 61b) is connected to an I/O data line IO via a column select transistor 61f. Gates of these column select transistors 61e and 61f are supplied with a column select signal CSLi.

The PDC comprises clocked inverter circuits 61i and 61j, and a transistor 61k which configure a latch circuit. The transistor 61k is connected between an input terminal of the clocked inverter circuit 61i and an input terminal of the clocked inverter circuit 61j, and has its gate supplied with a signal EQ1. A node N1a of this PDC and the node N2a of the SDC are connected by transistors 61g and 61h. The gate of the transistor 61g is supplied with a signal BLC2 and the gate of the transistor 61h is supplied with a signal BLC1.

In addition, a node N1b (the input terminal of the clocked inverter circuit 61j) of the PDC is connected to the gate of a transistor 611. One end of a current path of this transistor 611 is grounded via a transistor 61m. The gate of this transistor 61m is supplied with a signal CHK1. Moreover, the other end of the current path of the transistor 611 is connected to one end of a current path of transistors 61n and 61o, which transistors 61n and 610 configure a transfer gate. The gate of the transistor 61n is supplied with a signal CHK2n. In addition, the gate of the transistor 610 is connected to a connection node between the transistors 61g and 61h.

The other end of the current path of the transistors 61n and 610 is supplied with a signal COMi. This signal COMi is a signal common to all data storage circuits 10, and shows whether or not verify of all data storage circuits 10 has been completed, That is, as mentioned hereafter, when verify is completed, the node N1b of the PDC becomes “L”. If the signals CHK1 and CHK2n are set to “H” in this state when the verify is completed, the signal COMi becomes “H”.

The TDC is configured by a MOS capacitor 61p, for example. This MOS capacitor 61p is connected between a connection node N3 of the aforementioned transistors 61g and 61h and ground. In addition, the DDC is connected to the connection node N3 via a transistor 61q. The gate of the transistor 61q is supplied with a signal REG.

The DDC is configured by transistors 61r and 61s. One end of a current path of the transistor 61r is supplied with a signal VREG, and the other end of the current path of the transistor 61r is connected to a current path of the transistor 61q. The gate of the transistor 61r is connected to the node N1a of the PDC via the transistor 61s. The gate of this transistor 61s is supplied with a signal DTG.

In addition, the connection node N3 has one end of a current path of transistors 61t and 61u connected thereto. The transistor 61u has the other end of its current path supplied with a signal VPRE, and its gate supplied with a signal BLPRE.

The gate of the transistor 61t is supplied with a signal BLCLAMP. The other end of the current path of the transistor 61t is connected to the bit line BLi via a transistor 61v, and also to the bit line BLi+1 via a transistor 61w.

Another end of the bit line BLi is connected to one end of a current path of a transistor 61x. The gate of this transistor 61x is supplied with a signal BIASo. Another end of the bit line BLi+1 is connected to one end of a current path of a transistor 61y. The gate of this transistor 61y is supplied with a signal BIASe. The other end of the current path of these transistors 61x and 61y is supplied with a signal BLCRL. The transistors 61x and 61y are turned on in a complementary relationship with the transistors 61v and 61w in response to the signals BIASo and BIASe, thereby supplying an unselected bit line with a potential of the signal BLCRL.

[Programming Operation and Verify Operation]

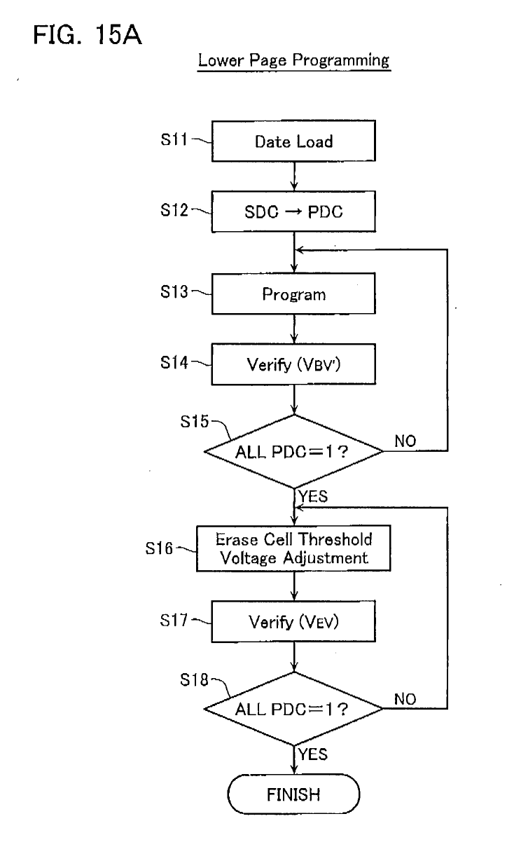

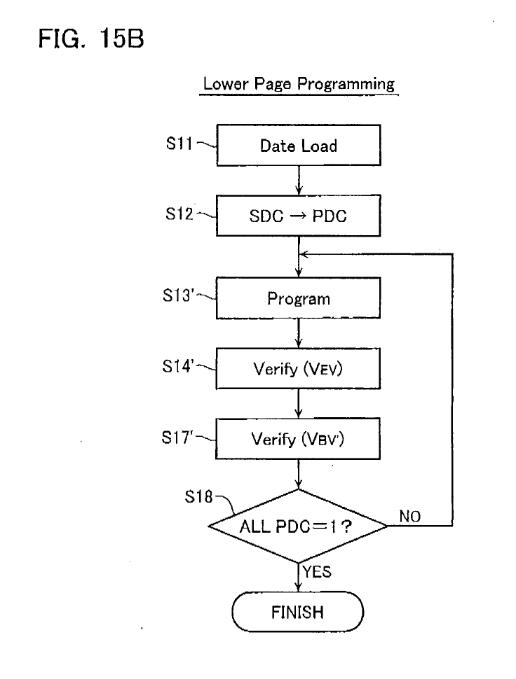

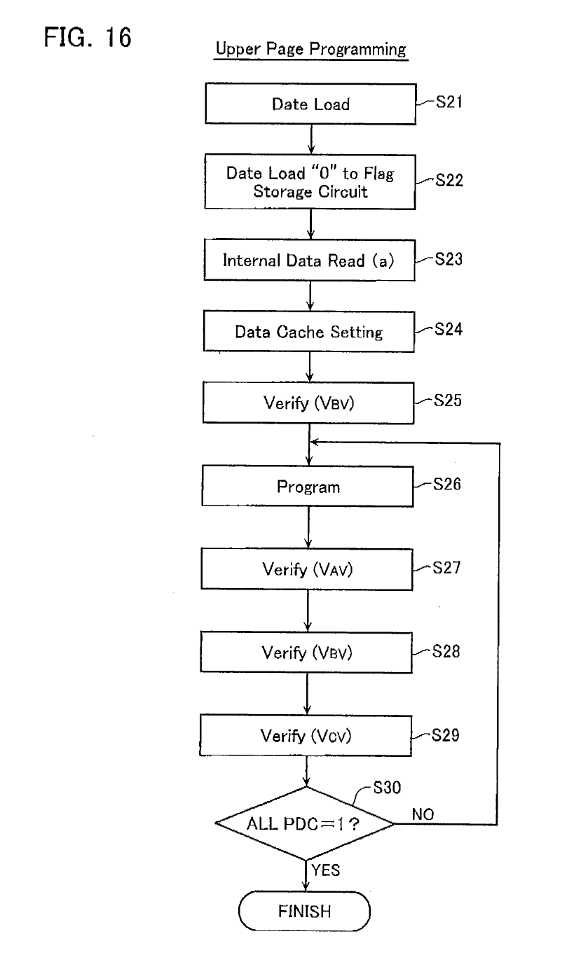

Next, a multi-value programming operation and programming verify operation in this NAND cell flash memory are described with reference to FIG. 15A, FIG. 15B and FIG. 16. As mentioned above, the programming operation is performed in the two stages of, namely, programming of lower page data and programming of upper page data.

As shown in FIG. 15A, first, an address is designated to select the lower page of one page, and then, programming data is inputted from outside to be stored in the SDCs in all of the data storage circuits 10 (S11).

Upon input of a programming command, data in the SDCs in all of the data storage circuits 10 is transferred to the PDCs (S12). In the case that data “1” is inputted from outside as lower page data, the node N1a of the PDC becomes “H”, and in the case that data “0” is inputted, the node N1a of the PDC becomes “L”. Note that in the programming operation of this lower page data, data is not stored in the flag cell FC. As a result, the PDC in the flag data storage circuit 10a becomes data “1”.

Then, the programming operation to the memory cells MC is proceeded to (S13), Specifically, the data retained in the PDCs is transferred to bit lines BLi and BLi+1. In the case that data “1” is retained in the PDC, the bit line becomes a power supply voltage Vdd, and in the case that data “0” is retained, the bit line becomes Vss (ground potential). Moreover, to prevent cells of an unselected page undergoing programming, the bit lines of the unselected page are also applied with the power supply voltage Vdd.

Here, the select line SG1 of the selected block is applied with the power supply voltage Vdd, the word line of the selected cells is applied with a potential VPGM (20 V), and the word lines of unselected cells are applied with a potential VPASS (10 V), This causes the selected cells to be programmed, while preventing programming in the unselected cells.

Then, the programming verify operation is proceeded to (S14). First, a potential Vread for during read is applied to the unselected word lines and the select line SG1, and the bit lines are pre-charged to 1 V. In addition, a verify potential VBv′ is applied to the selected word line. Then, the select line SG2 on the source side of the memory cells is set to “H”. If the threshold voltage of a selected memory cell MC is higher than the verify voltage VBv′, that memory cell MC stays off, whereby the bit line remains at “H”. In contrast, if the threshold voltage of the selected memory cell MC is lower than the verify voltage VBv′, that memory cell MC is turned on, and the bit line becomes “L”. The node N3 of the TDC becomes “L” in the case that the bit line is “L”, and becomes “H” when the bit line is “H”.

Here, “L” is stored in the DDC in the case that a “0” programming is performed, and “H” is stored in the DDC in the case that a “0” programming is not performed. If the signal VREG is set to Vdd and the signal REG set to “H”, the node N3 of the TDC forcibly becomes “H” only in the case that a “0” programming is not performed. Subsequent to this operation, data in the PDC is shifted to the DDC, and a potential of the TDC is transferred to the PDC.

In the case that the PDC is “L”, the programming operation is performed again, whereby the program operation and verify operation (S13-S15) are repeated as above until data of all of the data storage circuits becomes “H”. Subsequently, when programming is performed sequentially also on adjacent memory cells, then, depending on programming data, the threshold voltage of the memory cells rises due to capacitance between FGs, whereby the threshold voltage distribution of data “10” spreads in a high direction.

Then, the threshold voltage adjustment operation for memory cells MC that is to be maintained in the erase state (threshold voltage distribution E) is proceeded to (S15). Specifically, data “1” is stored in the PDC of the data storage circuits 10 connected to memory cells MC that are to be maintained in the erase state. In contrast, data “0” is stored in the PDC of the data storage circuits 10 connected to the other memory cells, that is, memory cells for which programming data “10” is completed. In the case that data “1” is retained in the PDC, the bit line BL becomes the power supply voltage Vdd, and in the case that data “0” is retained in the PDC, the bit line becomes Vss (ground potential). The other voltages applied in this step are similar to those of the step S13.

Then, the verify operation for adjusting a threshold voltage is proceeded to (S16). First, the potential Vread for during read is applied to the unselected word lines WL and the select line SG1, and the bit lines BL are pre-charged to 1 V. In addition, a verify potential VEV for adjustment of a lower limit of the threshold voltage distribution E is applied to the selected word line WL. Then, the select line SG2 on the source side of the memory cells is set to “H”. If the threshold voltage of a selected memory cell MC is higher than the verify voltage VEV, that memory cell MC stays off, whereby the bit line remains at “H”. If the threshold voltage of the selected memory cell MC is lower than the verify voltage VEV, that memory cell MC is turned on, and the bit line becomes “L”. The node N3 of the TDC becomes “L” in the case that the bit line is “L”, and becomes “H” in the case that the bit line is “H”.

In the case that the PDC is “L”, the programming operation is performed again, whereby the threshold voltage adjustment operation and verify operation (S15-S17) are repeated as above until data of all of the data storage circuits 10 becomes “H”. The lower limit value of the threshold voltage distribution E of the memory cells MC in the erase state is thereby adjusted, allowing effects on other memory cells to be reduced.

Alternatively, it is possible to perform operations for adjusting a lower limit value of the threshold voltage distribution E (S16-S18) prior to the program operation (S13). In this case, it is possible to reduce the amount of variation in threshold voltage in the threshold voltage distribution B′.

Moreover, as shown in FIG. 15B, it is possible to execute the program operation (S13′) and the operation for adjusting a lower limit value of the threshold voltage distribution E (S14′) in a row. For example, in the program operation (S13′), the select line SG1 of the selected block is applied with the power supply voltage Vdd, the word line of the selected cell is applied with a potential VPGM (20 V), and the word lines of unselected cells are applied with a potential VPASS (10 V). In addition, in the case that data “1” is retained in the PDC, the bit line is provided with a voltage slightly higher than the ground potential Vss, and in the case that data “0” is retained, the bit line becomes Vss (ground potential). As a result, memory cells in the erase state is slightly programmed, thereby the threshold voltage distribution E can be made higher. In addition, the program operation (S13′) and adjustment of a lower limit value of the threshold voltage distribution E (S14′) may be conducted at the same time, thereby improving the operation speed.

Next, the programming operation of upper page data is described with reference to FIG. 16. Likewise in the programming operation of upper page data, first, an address is designated, and then, programming data is inputted from outside to be stored in the SDCs in all of the data storage circuits 10 (S21).

Then, upon input of a programming command, “0” is stored to the flag cell FC as flag data FLAG, resulting in data “0” being inputted to the SDC in the flag data storage circuit 10a (S22).

Subsequently, an internal read operation is performed to judge whether data after programming operation of upper page is “11” (lower page data is “1”) or “10” (lower page data is “0”) (S23). The selected word line is applied with the potential VA (FIG. 1). The unselected word lines and the select line SG1 are applied with the potential Vread. In the case that data in the memory cell is “10”, “H” is latched in the PDC, and when data in the memory cell is “11”, “L” is latched in the PDC.

Then, data to be stored in each of the data caches SDC, PDC, TDC, and DDC is set according to which of “11”, “01”, “10”, and “00” the data desired to be written is (S24).

Subsequently, and prior to the programming operation, verify of data “10” is performed (S25). Then, the programming operation is executed similarly to the programming operation of lower page data (S26).

In addition, verify operations are performed for data “01”, “10”, and “00”, setting a potential to VAv, VBv, and VCv, respectively (S27-S29), and the read operation and verify operation are repeated until data in the PDC of all of the data storage circuits 10 becomes “H” (S30).

### SECOND EMBODIMENT

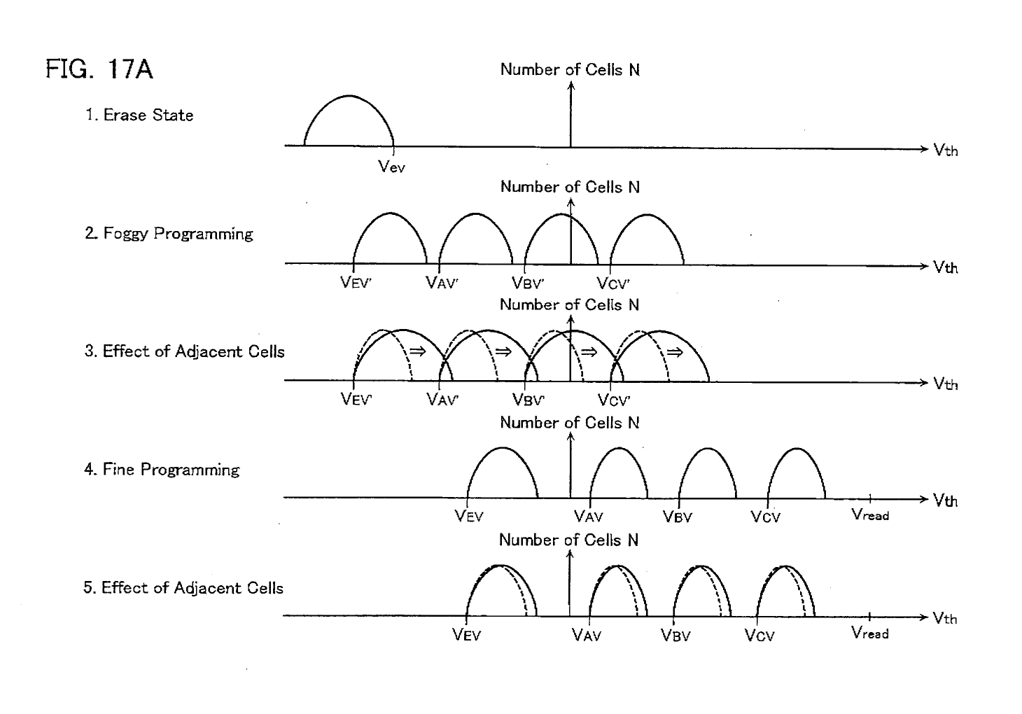

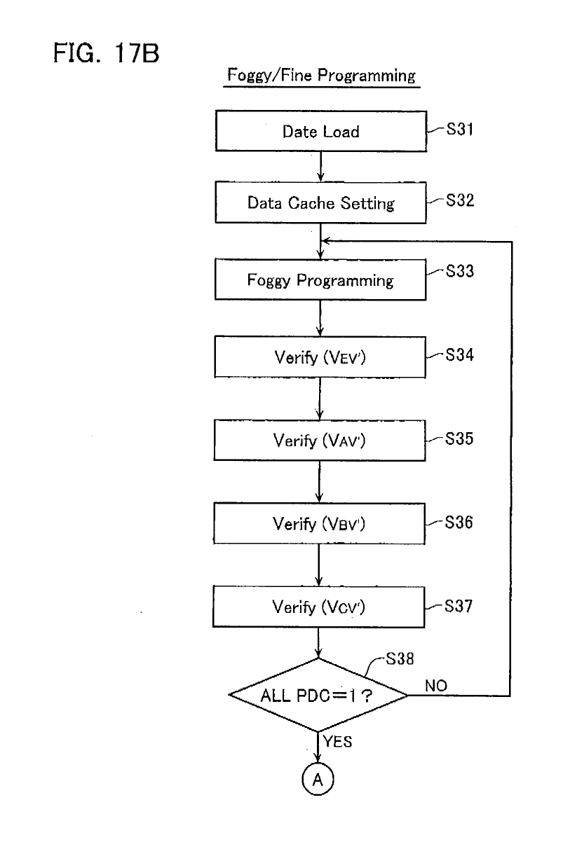

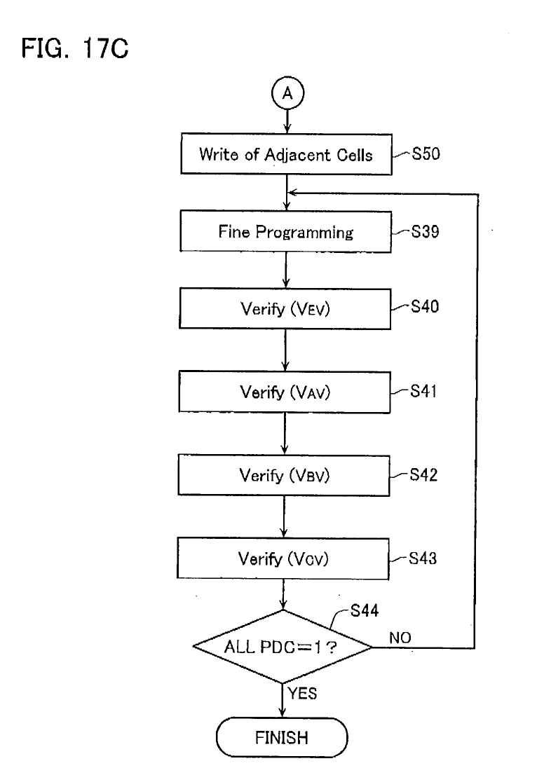

Next, a nonvolatile semiconductor memory device of a second embodiment of the present invention is described with reference to FIG. 17A to FIG. 17C, This embodiment differs from the first embodiment in that two stages of programming operation are executed therein, namely, a foggy programming operation which is a rough programming of the upper page data/lower page data, and a fine programming operation which is a precise programming of the upper page data/lower page data. Moreover, in each of these foggy programming operation and fine programming operation, a verify voltage is used to adjust the lower limit value of the threshold voltage distribution E of the memory cells in the erase state. As a result, similar advantages to the first embodiment can be obtained. Circuit configurations as shown in FIGS. 9-14 may be adopted, and descriptions thereof are thus omitted.

A programming operation in the four-value storage, system including the foggy programming operation and fine programming operation is described with reference to FIG. 17A. First, from a state where all of the memory cells are erased (1), the foggy programming operation is executed on a certain memory cell MCn (2). The foggy programming operation is a programming operation to obtain threshold voltage distributions E′, A′, B′, and C′, by utilizing verify voltages VEV′, VAV′, VBV′, and VCV′ that are less than the lower limit values of the plurality of threshold voltage distributions E, A, B, and C that are to be obtained in the final stage, as shown in FIG. 17. That is, as shown in FIG. 17B, after performing the above-described foggy programming operation, verify operations (S34-37) are performed. Thereafter, a fine programming operation (S39) is performed. Then, verify operations are performed (S40-S43). In addition, between the foggy programming operation and the fine programming operation, a programming operation to the adjacent memory cell is conducted (S50).

As shown in FIG. 17C, when programming is executed on memory cells adjacent to the above-mentioned memory cell MCn after the verify operation (S34-37), the threshold voltage distributions E′, A′, B′, and C′ after the foggy programming operation are respectively shifted in the positive direction (see [3.] in FIG. 17C). The foggy programming operation is a rough programming operation, and the difference between each of the verify voltages VEV′, VAV′, VBV′, and VCV′ is also set less than the difference between verify voltages VEV, VAV, VBV, and VCV of the fine programming operation. As a result, variations in the threshold voltage distributions due to the effects of adjacent memory cells may in cases cause the respective distributions to overlap with each other.

Subsequently, as shown in FIG. 17C, the fine programming operation (S39) is performed on the memory cell MCn. The fine programming operation is an operation to shift the threshold voltage distributions E′, A′, B′, and C′ in the positive direction to obtain the threshold voltage distributions E, A, B, and C, by utilizing the verify voltages VEV, VAV, VBV, and VCV that are equal to the lower limit values of the plurality of threshold voltage distributions E, A, B, and C that is to be obtained finally (see [4.] in FIG. 17A). Likewise in this fine programming operation, the verify voltage VEV is used for the verify operation (S40) to adjust the lower limit value of the threshold voltage distribution in the threshold voltage distribution E′. Although this verify voltage VEV has a negative value (a negative value in an equivalent sense) similarly to the verify voltage VEV′ used in the foggy programming operation, its value is greater than (its absolute value is less than) that of the verify voltage VEV′. Note that these verify voltages VEV and VEV′ are also determined with consideration for the read voltage Vread. Verify operations for the threshold voltage distributions A, B, and C are also performed (S41-44), as is similar to those of the first embodiment.

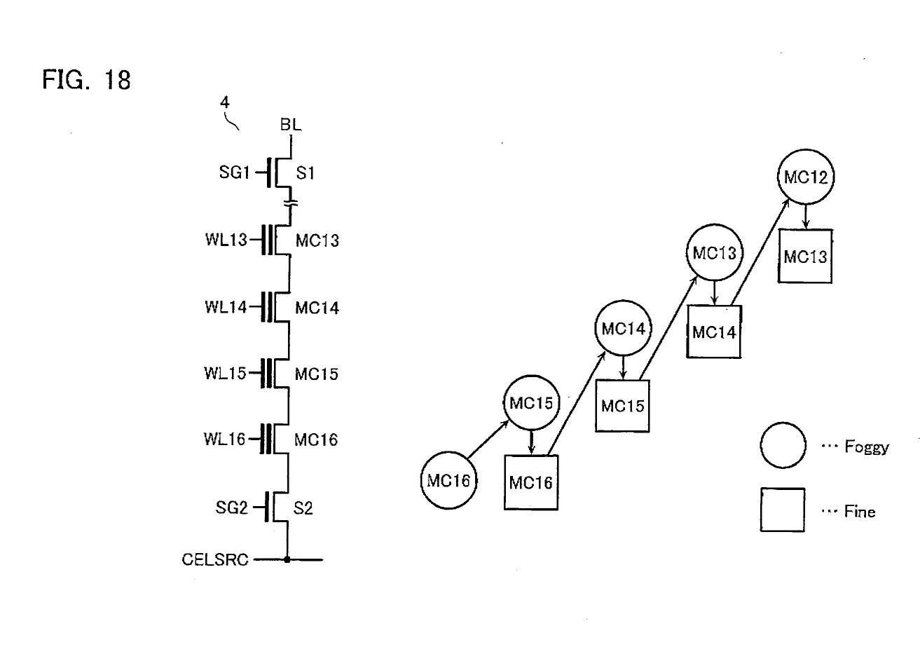

After this fine programming operation, some variation occurs in the threshold voltage distributions E, A, B, and C due to the programming operation on adjacent memory cells. However, the amount of variation can be reduced by innovation in programming procedures and so on. One example of a programming procedure for reducing variation in the threshold voltage distribution is described with reference to FIG. 18. Generally, in a NAND cell flash memory, programming is performed sequentially from memory cell MC16 on a side near the common source line CELSRC in one NAND string, with furthest memory cell MC1 being programmed last.

In case of performing the above-described foggy programming operation and fine programming operation on such a NAND string, variation in the threshold voltage distribution can be suppressed to a minimum by executing the programming procedure as in FIG. 18. First, the foggy programming operation is executed on the memory cell MC16 nearest to the common source line CELSRC. Then, subsequent to performing the foggy programming operation on adjacent memory cell MC15, the procedure returns to the memory cell MC16 and the fine programming operation is performed for the memory cell MC16.

In the next step, the foggy programming operation is performed not on the memory cell MC15 adjacent to the memory cell MC16, but on memory cell MC14 two apart in a bit line BL direction from the memory cell MC16. As a result, the variation in the threshold voltage distribution of the memory cell MC16 is suppressed. Then, the fine programming operation is performed on the memory cell MC15. Although the threshold voltage distribution of the memory cell MC15 subsequent to the foggy programming operation may be expected to undergo variation due to the foggy programming to the memory cell MC14, such effects are overcome by this fine programming operation.

Thereafter as well, this procedure, namely, to perform the foggy programming on a memory cell MCn−2 two apart in the bit line BI direction from a memory cell MCn in which fine programming operation is completed, and then to go back one and execute the fine programming on a memory cell MCn−1, is repeated as far as the memory cell MC1. This enables effects of adjacent memory cells in a memory cell array where foggy/fine programming is executed to be suppressed to a minimum.

This concludes description of embodiments of the present invention, but it should be noted that the present invention is not limited to the above-described embodiments, and that various alterations, additions, and so on, are possible within a range not departing from the scope and spirit of the invention. For example, in the above-described embodiments, a nonvolatile semiconductor memory device of the four-value storage system (two bits per cell) is described. However, the present invention is of course not limited to these embodiments, and is applicable also to storage systems of more numerous bits, such as an eight-value storage system.

What is claimed is:

1. A nonvolatile semiconductor memory device, comprising:
a memory cell array having a plurality of memory cells arranged therein, each of the memory cells configured to store multiple bits of data by way of a threshold voltage distribution having a negative value and representing an erase state, and a plurality of threshold voltage distributions each having a value higher than the threshold voltage distribution representing the erase state and representing a programming state; and
a control circuit configured to control a programming operation for storing data to the memory cells, a programming verify operation for confirming the data to the memory cells, and a read operation for reading the data from the memory cells,
the control circuit being operative to apply, in the programming verify operation, a certain verify voltage to a control gate of one of the memory cells which is to be programmed to obtain a threshold voltage distribution higher than the threshold voltage distribution representing the erase state, thereby confirming the programming state of the memory cell, and apply, in the programming verify operation, a certain verify voltage to a control gate of one of the memory cells maintained in the erase state, thereby adjusting a lower limit value of the threshold voltage distribution representing the erase state.

2. The nonvolatile semiconductor memory device according to claim 1,
wherein the verify voltage applied to the control gate of one of the memory cells maintained in the erase state has a negative value.

3. The nonvolatile semiconductor memory device according to claim 1,
wherein the control circuit is configured to enable execution of:
a foggy programming operation in which a third verify voltage less than a lower limit value of any one of the threshold voltage distributions representing the programming state are used to shift the threshold voltage distribution representing the erase state in a positive direction; and
a fine programming operation in which a fourth verify voltage equal to a lower limit value of any one of the threshold voltage distributions representing the programming state are used to shift the threshold voltage distributions after the foggy programming operation further in the positive direction,
wherein, in the foggy programming operation, a first verify voltage is applied to one of the memory cells maintained in the erase state, thereby adjusting the lower limit value of the threshold voltage distribution representing the erase state, and
wherein, in the fine programming operation, a second verify voltage having an absolute value smaller than the first verify voltage is applied to one of the memory cells maintained in the erase state, thereby adjusting the lower limit value of the threshold voltage distribution representing the erase state.

4. The nonvolatile semiconductor memory device according to claim 3,
wherein the first verify voltage and the second verify voltage are set according to a value of a read voltage, the read voltage being applied to unselected memory cells during the read operation and the read voltage having such a value that renders one of the memory cells conductive irrespective of data retained therein.

5. The nonvolatile semiconductor memory device according to claim 1,
wherein the memory cell array includes a plurality of memory strings arranged therein, each of the memory strings including a plurality of the memory cells connected in series.

6. The nonvolatile semiconductor memory device according to claim 3,
wherein the control circuit performs the foggy programming operation on a second memory cell that is two apart in a bit line direction from a first memory cell for which the fine programming operation has been completed, and then executes the fine programming operation on a third memory cell that is adjacent to the first memory cell in the bit line direction and has undergone completion of the foggy programming operation.

7. The nonvolatile semiconductor memory device according to claim 6,
wherein the first verify voltage and the second verify voltage are set according to a value of a read voltage, the read voltage being applied to unselected memory cells during the read operation and the read voltage having such a value that renders one of the memory cells conductive irrespective of data retained therein.

8. A nonvolatile semiconductor memory device, comprising:
a memory cell array having a plurality of memory cells arranged therein, each of the memory cells configured to store multiple bits of data by way of a threshold voltage distribution having a negative value and representing an erase state, and a plurality of threshold voltage distributions each having a value higher than the threshold voltage distribution representing the erase state and representing a programming state; and
a control circuit configured to control a programming operation for storing data to the memory cells, a programming verify operation for confirming the data to the memory cells, and a read operation for reading the data from the memory cells,
the control circuit being configured to enable execution of:
a foggy programming operation in which the threshold voltage distribution representing the erase state is shifted to any one of intermediate threshold voltage distributions, each of the intermediate threshold voltage distributions corresponding to one of a plurality of the threshold voltage distributions representing the programming state, and having a lower limit value smaller than a lower limit value of the corresponding one of the plurality of the threshold voltage distributions representing the programming state; and
a fine programming operation in which each of the intermediate threshold voltage distributions is further shifted to a positive direction to obtain the plurality of the threshold voltage distributions representing the programming state,
wherein the foggy programming operation sets a lower limit value of the threshold voltage distribution of the memory cell that is to be maintained in the erase state to a first verify voltage, and
the fine programming operation sets a lower limit value of the threshold voltage distribution of the memory cell that is to be maintained in the erase state to a second verify voltage having an absolute value smaller than the first verify voltage.

9. The nonvolatile semiconductor memory device according to claim 8,
wherein the control circuit applies, in the read operation, a read voltage to control gates of unselected memory cells, the read voltage having such a value that renders one of the memory cells conductive irrespective of data retained therein.

10. The nonvolatile semiconductor memory device according to claim 8, wherein the first verify voltage and the second verify voltage have a negative value.

11. The nonvolatile semiconductor memory device according to claim 8,
wherein the control circuit shifts, in the foggy programming operation, the threshold voltage distribution of the memory cell that is to be maintained in the erase state in a positive direction,

12. The nonvolatile semiconductor memory device according to claim 11,
wherein the first verify voltage and the second verify voltage are set according to a value of a read voltage, the read voltage being applied to unselected memory cells during the read operation and the read voltage having such a value that renders one of the memory cells conductive irrespective of data retained therein.

13. The nonvolatile semiconductor memory device according to claim 8,
wherein the control circuit shifts, in the fine programming operation, the threshold voltage distribution of the memory cell that is to be maintained in the erase state in a positive direction.

14. The nonvolatile semiconductor memory device according to claim 11,
wherein the control circuit performs the foggy programming operation on a second memory cell that is two apart in a bit line direction from a first memory cell for which the fine programming operation has been completed, and then executes the fine programming operation on a third memory cell that is adjacent to the first memory cell in the bit line direction and has undergone completion of the foggy programming operation.

15. The nonvolatile semiconductor memory device according to claim 10,
wherein the control circuit shifts, in the fine programming operation, the threshold voltage distribution of the memory cell that is to be maintained in the erase state in a positive direction.

16. A method of programming data in a nonvolatile semiconductor memory device, the nonvolatile semiconductor memory device including a memory cell array including a plurality of memory cells arranged therein, each of the memory cells configured to store multiple bits of data by way of a threshold voltage distribution having a negative value and representing an erase state, and a plurality of threshold voltage distributions each having a value higher than the threshold voltage distribution representing the erase state and representing a programming state, the method comprising:
applying a certain verify voltage to a control gate of one of the memory cells which is to be programmed to obtain a threshold voltage distribution higher than the threshold voltage distribution representing the erase state, thereby confirming the programming state of the memory cell; and
applying a certain verify voltage to a control gate of one of the memory cells that is to be maintained in the erase state, thereby adjusting a lower limit value of the threshold voltage distribution representing the erase state.

17. The method of programming data in a nonvolatile semiconductor memory device according to claim 16,
wherein the verify voltage applied to the control gate of one of the memory cells maintained in the erase state has a negative value.

18. The method of programming data in a nonvolatile semiconductor memory device according to claim 16, further comprising:
using, in a foggy programming operation, a third verify voltage less than 4 lower limit value of any one of the threshold voltage distributions representing the programming state to shift the threshold voltage distribution representing the erase state in a positive direction; and
using, in a fine programming operation, a fourth verify voltage equal to a lower limit value of any one of the threshold voltage distributions representing the programming state to shift the threshold voltage distributions after the foggy programming operation further in the positive direction,
wherein, in the foggy programming operation, a first verify voltage is applied to one of the memory cells maintained in the erase state, thereby adjusting the lower limit value of the threshold voltage distribution representing the erase state, and
wherein, in the fine programming operation, a second verify voltage having an absolute value smaller than the first verify voltage is applied to one of the memory cells maintained in the erase state, thereby adjusting the lower limit value of the threshold voltage distribution representing the erase state.

19. The nonvolatile semiconductor memory device according to claim 18,
wherein the foggy programming operation is performed on a second memory cell that is two apart in a bit line direction from a first memory cell for which the fine programming operation has been completed, and then the fine programming operation is executed on a third memory cell that is adjacent to the first memory cell in the bit line direction and has undergone completion of the foggy programming operation.
